(19) United States
(12) Patent Application Publication
(10) Pub. No.: US 2010/0187516 A1
(43) Pub. Date: Jul. 29, 2010

(54) ORGANIC SEMICONDUCTOR DEVICE AND METHOD FOR MANUFACTURING ORGANIC SEMICONDUCTOR DEVICE

(75) Inventors: Tatsuya Yoshizawa, Tsurugashima-shi (JP); Takuya Hatakeyama, Tsurugashima-shi (JP); Yohei Tanaka, Tsurugashima-shi (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION, MEGURO-KU, TOKYO (JP)

(21) Appl. No.: 12/666,990

(22) PCT Filed: Jun. 29, 2007
(86) PCT No.: PCT/JP2007/063146

§ 371 Date: Dec. 28, 2009

(51) Int. Cl. H01L 51/05; H01L 51/42; H01L 51/50

(52) U.S. Cl. 257/40; 257/E51.025; 257/E51.026

(57) ABSTRACT

An organic semiconductor device of preventing invasion of hydrogen or hydrogen ion into the device and having a long-term reliability, and a method of manufacturing thereof are provided by giving a hydrogen absorbing layer which absorbs hydrogen or hydrogen ion, and which does not release the absorbed hydrogen or hydrogen ion.

The organic semiconductor device comprises at least a substrate 10, a first electrodell, an organic functional component 12, a second layer 13, and a hydrogen absorbing layer 14 which absorbs hydrogen or hydrogen ion, and which does not release the absorbed hydrogen or hydrogen ion.

### TECHNICAL FIELD

This invention is related to an organic semiconductor device and a method for manufacturing the organic semiconductor device.

### BACKGROUND ART

With respect to the semiconductor device, it has been generally known that heat which is applied to the device during the manufacturing processes thereof, or hydrogen, hydrogen ion, oxygen and water which were happened to generate due to certain external perturbations exert influences upon the long-term reliability of the semiconductor device. In addition, it has been also known that, even after the manufacturing of the device, hydrogen, hydrogen ion, oxygen and water which were happened to generate due to other certain external perturbations exert influences upon the long-term reliability of the semiconductor device.

Particularly, since the hydrogen is the light weight atom, it can easy reach the interior of the semiconductor device (for instance, a first electrode, an organic functional layer, and a second electrode), and thus it brings an adverse influence to the long-term reliability of the semiconductor device. For instance, on the organic EL element, problems such as the degression in the element's properties and the shortening of the element's lifetime, are caused by the influence of the hydrogen or hydrogen atom. In addition, owing to the growth of the dark spot(s) caused by the influence of the hydrogen or hydrogen atom, the problem that quantity of light which is emitted by the organic EL element becomes lower along the time course, i.e., the progress of non-luminescence, arises.

Furthermore, with respect to the active organic EL, a problem that the invasion of hydrogen brings adverse influences such as fluctuations of VTH in TFT also arises.

Under such a situation, in Patent Literature 1, a technique for preventing the invasion of oxygen and water is disclosed, wherein a protective layer is provided, the protective layer being made of a glass which comprises a glass forming material and glass modifiers of oxide and sulfide which are doped into the glass forming material, and which has a dense structure as compared with that of the glass which includes only the glass forming material.

In Patent Literature 2, a technique that a silicon resistance layer in a silicon device is covered with a Ti (titanium) type barrier metal film so as to absorb hydrogen existing in the silicon resistance layer is disclosed.

Patent Literature 1: JP Hei 11-097169 A

Patent Literature 2: JP 2001-168287 A

### DISCLOSURE OF THE INVENTION

### Problems to be Solved by the Invention

However, the protective layer disclosed in Patent Literature 1 is provided by forming a glass which has a dense structure as compared with that of the glass which includes only the glass forming material, and prohibits the invasion of oxygen and water into the device. Although the protective layer can prohibit the invasion of oxygen and water into the device, but it can not prohibit the invasion of hydrogen or hydrogen atom.

In Patent Literature 2, since the Ti type barrier metal film can absorb hydrogen, it protects the device from the invasion of hydrogen temporary. However, because the bond energy between hydrogen and Ti is weak, the barrier metal film tends to cut off the once absorbed hydrogen and release it again. Therefore, the again released hydrogen can invade into the device. Thus, the perfect prohibition of the hydrogen invasion can not be attained.

The present invention is contrived by concerning the above mentioned situations, and it's a main subject is to provide an organic semiconductor device which can protect the respective layers which constitute the device from the invasion of hydrogen or hydrogen ion, and thus which has a long-term reliability, and a method for manufacturing such an organic semiconductor device.

### Means for Solving the Problems

The organic semiconductor device claimed in claim 1 comprises at least a substrate, a first electrode, an organic functional component, and a second layer, which are layered in this order, and which further comprises a hydrogen absorbing layer which is provided onto or above the second layer, wherein the hydrogen absorbing layer comprises one member selected from the group consisting of alkaline metals, alkaline earth metals, metals having a high affinity for hydrogen, and metal compounds including any one of these metals as metal component thereof.

### BRIEF DESCRIPTION OF THE DRAWINGS

FIG. 1 is a sectional view which illustrates an embodiment of a semiconductor device having a hydrogen absorbing layer.

FIG. 2 is a view which illustrates a panel with a division wall into which a semiconductor device having a hydrogen absorbing layer is applied.

FIG. 3 is a process drawing which briefly illustrates the manufacturing method according to the present invention.

### EXPLANATION OF NUMERALS

100, 200 - - - Organic semiconductor device
10, 30 - - - Substrate
11, 31 - - - First electrode
12, 32 - - - Organic functional component
13, 33 - - - Second electrode
14, 34 - - - Hydrogen absorbing layer
16 - - - Division wall
15, 35 - - - Protective layer

### BEST MODE FOR CARRYING OUT THE INVENTION

First, the organic semiconductor device according to the present invention will be described concretely with reference to the drawings.

### (1) First Embodiment of the Organic Semiconductor Device According to the Present Invention

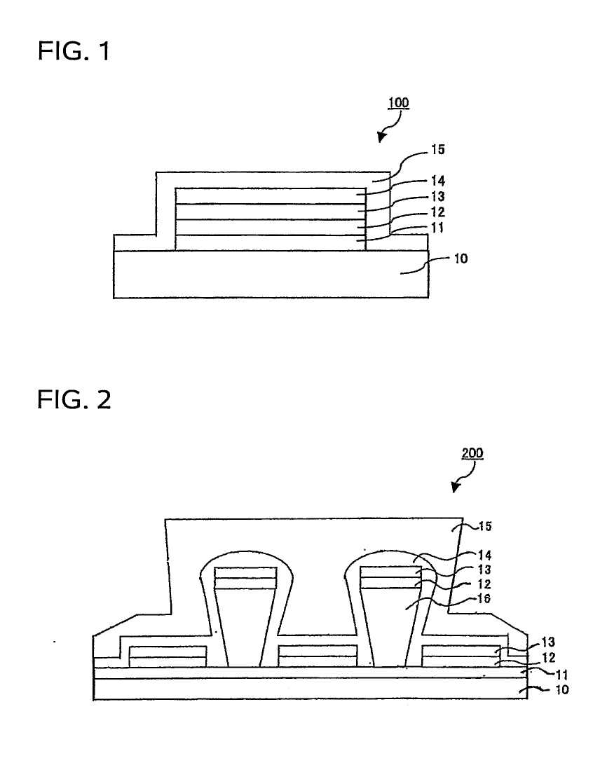

FIG. 1 is a sectional view which illustrates an embodiment of a semiconductor device having a hydrogen absorbing layer according to the present invention.

As shown in FIG. 1, the organic semiconductor device 100 according to the present invention which has a hydrogen absorbing layer comprises at least a substrate 10, a first electrode 11, an organic functional component 12, and a second layer 13, which are mutually layered in this order, and which further comprises a hydrogen absorbing layer 14 which is provided onto or above the second layer 13, wherein the hydrogen absorbing layer 14 is able to absorb hydrogen and hydrogen ion, and which does not release the absorbed hydrogen or hydrogen ion. As mentioned above, when the hydrogen absorbing layer 14 which absorbs hydrogen and hydrogen ion, and which does not release the absorbed hydrogen or hydrogen ion is provided as a layer which constitutes a part of the organic semiconductor device, it becomes possible to prevent the respective layers which constitute the organic semiconductor device from invasion of hydrogen or hydrogen ion which is generated due to heat created during the manufacturing steps of the device, and due to ion-detachment during the film production using plasma as mentioned later, and from invasion of hydrogen or hydrogen ion which is generated after the manufacturing of the device.

Now, the respective layers which constitute the organic semiconductor device 100 will be described sequentially.

### (Substrate)

As shown in FIG. 1, the substrate 10 in the organic semiconductor device 100 functions as a base for stacking various thin layers and so on, which consists the organic semiconductor device as described below.

As material of the substrate 10, there is no particular limitation as far as it can function as the basis, and it can be selected arbitrarily in accordance with the use of the organic semiconductor device intended. Concretely, for instance, glass, silicon oxide, various resins, and so on, can be enumerated.

In addition, the substrate 10 is not necessarily constituted by a single layer (in FIG. 1, the substrate has a single layer's structure.), but it may be constituted by two or more of the above mentioned materials with taking a layered structure. With respect to the thickness of the substrate 10, there is no particular limitation.

Further, with respect to the method for preparing the substrate 10 which is used in the organic semiconductor device according to the present invention, there is no particular limitation and it is able to utilize appropriately any one of known procedures for preparing the substrate.

### (First Electrode)

As shown in FIG. 1, the first electrode 11 in the organic semiconductor device 100 according to the present invention is formed onto the substrate 10 as mentioned above, and it is provided so as to apply a potential to an organic functional component 12 which is layered onto the substrate 10, in cooperation with the second electrode 13 described below.

As material of the first electrode 11, there is no particular limitation, and it can be selected arbitrarily from various materials as far as it can function as mentioned above. Concretely, for instance, various metals (including alloys thereof) can be enumerated, and more concretely, Ag (silver), Al (Aluminum), ITO (indium tin oxide), and other various low resistance materials can be enumerated.

The first electrode 11 can be colored or can be a non-colored transparent one depending upon the usage of the organic semiconductor device 100. The thickness of the first electrode 11 is preferably in the range of 10 nm-1000 nm.

Further, with respect to the method for preparing such first electrode 11, there is no particular limitation and it is able to utilize appropriately any one of known procedures for preparing the electrode. Concretely, for instance, the photolithographic patterning method may be mentioned.

### (Organic Functional Component)

As shown in FIG. 1, the organic functional component 12 in the organic semiconductor device 100 according to the present invention is essential for functioning actually the organic semiconductor device. Depending upon the kind of the organic semiconductor device intended, the constitution of the organic functional component is also appropriately selected.

Generally, the organic functional component 12 may be formed by stacking various kinds of thin layers, and thus, the organic functional component 12 is not necessarily constituted by a single layer (in FIG. 1, the organic functional component has a single layer's structure.). For instance, the organic functional component 12 may be constituted by a high molecular organic functional layer and a low molecular organic functional layer in layered structure thereof. Alternatively, when the organic semiconductor device 100 of the present invention is intended to use as an organic EL device, the organic functional component 12 may be constituted by stacking a high polymer organic functional layer, an electron hole transporting layer, an organic luminescent layer, an electron injection layer, and the like in this order.

As material of the organic functional layer(s) which constitutes the organic functional component 12, there is no particular limitation, and it can be selected arbitrarily from various materials as far as it can function as mentioned above.

Further, with respect to the method for preparing the organic functional layer(s) which constitutes the organic functional component 12, there is no particular limitation and it is able to utilize appropriately any one of known procedures for preparing the organic functional layer(s). Concretely, for instance, when a high molecular organic functional layer is formed, wet coating methods such as spin coating, spin coating, splaying, ink-jet printing, etc., may be utilized. When a low molecular organic layer is formed, vacuum deposition method or the like may be utilized. Alternatively, when the high polymer organic functional layer, the electron hole transporting layer, the organic luminescent layer, the electron injection layer, and the like are stacked in this order, for instance, ohmic-resistance heating deposition method or the like may be adaptable.

### (Second Electrode)

As shown in FIG. 1, the second electrode 13 in the organic semiconductor device 100 according to the present invention is formed onto the organic functional component 12 as mentioned above, and it is provided so as to apply a potential to the organic functional component 12, in cooperation with the first electrode 11 described above.

As material of the second electrode 13, there is no particular limitation, and it can be selected arbitrarily from various materials as far as it can function as mentioned above. Concretely, for instance, various metals (including alloys thereof) which are similar with those described above as for the first electrode 11, and other various low resistance materials can be enumerated.

The second electrode 13 can be colored or can be a non-colored transparent one depending upon the usage of the organic semiconductor device 100. The thickness of the second electrode 13 is preferably in the range of 10 nm-1000 nm.

Further, with respect to the method for preparing such second electrode 13, there is no particular limitation and it is able to utilize appropriately any one of known procedures for preparing the electrode. Concretely, for instance, when aluminum is used for the second electrode, ohmic-resistance heating deposition method for aluminum, or the like, may be adaptable.

### (Hydrogen Absorbing Layer)

As shown in FIG. 1, the hydrogen absorbing layer 14 in the organic semiconductor device 100 according to the present invention is formed onto or above the second electrode 13 as mentioned above, and it is provided so as to be able to absorb hydrogen and hydrogen ion which are generated during or after the manufacturing process of the organic semiconductor device, and which does not release the absorbed hydrogen or hydrogen ion.

With respect to the formation of the hydrogen absorbing layer which should perform the functions as mentioned above, we, the inventors have made selection of the material of the hydrogen absorbing layer in consideration of the following points.

Namely, the material of the hydrogen absorbing layer is selected from (1) materials which can absorb hydrogen and hydrogen ion and can not release the absorbed hydrogen or hydrogen ion and (2) materials which have a high absorbing capability against hydrogen and hydrogen ion, and, even when which may release the once absorbed hydrogen or hydrogen ion, which are able to re-absorb them immediately after releasing.

When the hydrogen absorbing layer is formed with any one of the above mentioned materials (1) and (2), it becomes possible to retain the hydrogen or hydrogen ion within the hydrogen absorbing layer as a whole, and thus, the adverse effect of the hydrogen or hydrogen ion against the individual layers which constitutes the organic semiconductor device can be excluded.

First, the materials (1) which can absorb hydrogen and hydrogen ion and can not release the absorbed hydrogen or hydrogen ion as the material of the hydrogen absorbing layer 14 will be described as follows.

In general, when the hydrogen absorbing layer 14 absorbs hydrogen or hydrogen ion, hydride is produced by reacting the material which constitute the hydrogen absorbing layer 14 with the hydrogen or hydrogen ion.

Herein, the hydride which is produced from the material which constitute the hydrogen absorbing layer 14 with the hydrogen or hydrogen ion reduces its tendency to release the hydrogen or hydrogen atom absorbed in the hydrogen absorbing layer 14 as the binding energy of the hydride becomes higher. Therefore, it is preferable that the hydrogen absorbing layer 14 of the organic semiconductor device according to the present invention is that of contributing a high binding energy of the hydride which is formed when the hydrogen or hydrogen ion is absorbed into the hydrogen absorbing layer 14. Concretely, it is preferable that the hydrogen absorbing layer 14 is made of a material which contributes a high binding energy of the hydride.

As the material of the hydrogen absorbing layer 14 which can contribute such a function, metals or metal compounds are desirable. Further, metals or metal compounds which can produce the hydride via ionic bond(s) with the hydrogen(s) or hydrogen ion(s), wherein the hydride thus produced becomes an ionic hydride, are more desirable.

Since the ionic hydride which is produced by ionic bond possesses a high binding energy and thus it becomes stable, it become possible to retain the hydrogen even at a high temperature region. Thus, the hydrogen or hydrogen ion once absorbed in the hydrogen absorbing layer 14 is never released.

As such a metal or metal compound which bonds to hydrogen(s) or hydrogen(s) ion via ionic bond(s) and thereby forms an ionic hydride, alkaline metals and alkaline earth metals, as well as metal compounds which include one of such metals as one component are enumerated concretely. These metals form ionic bond(s) with hydrogen(s), and produce ionic hydride.

2M^{I}+H₂→2M^{I}H M^{I}=alkaline metal

M^{II}+H₂→M^{II}H₂ M^{II}=alkaline earth metal

As the alkaline metal, for instance, Li (lithium), Na (Sodium), K (potassium), Rb (rubidium), Cs (cesium), etc., are enumerated, and as the alkaline earth metal, for instance, Be (beryllium), Mg (magnesium), Ca (calcium), Sr (strontium), Ba (barium), etc., are enumerated. Further, as the metal compound which includes one of such metals, for instance, LiF (lithium fluoride), Li₂O (lithium oxide), CaO (calcium oxide), BaO (barium oxide), BaF₂ (barium fluoride), CaF₂ (calcium fluoride), etc., are enumerated.

Further, the binding energy of the hydride is dominated by the heat of formation (standard enthalpy of formation), ΔH, of the hydride, and the binding energy of the hydride becomes higher as the ΔH value becomes lower.

Thus, it is preferable that the hydrogen absorbing layer 14 is made of a material which provides a lower value of heat of formation (standard enthalpy of formation), ΔH, of the hydride which is formed when the hydrogen absorbing layer 14 absorbs hydrogen or hydrogen ion. More concretely, it is preferable that the hydrogen absorbing layer 14 is made of a material which provides a value of heat of formation (standard enthalpy of formation), ΔH, of the hydride being not more than −90 kJ/mol.

As the material which constitutes the hydrogen absorbing layer 14 with providing such a heat of formation (standard enthalpy of formation), ΔH, value, for instance, Li (lithium), Ba (barium), Ca (calcium), etc., are enumerated. As the metal compound which includes one of such metals, for instance, LiF (lithium fluoride), Li₂O (lithium oxide), Cao (calcium oxide), BaO (barium oxide), BaF₂ (barium fluoride), CaF₂ (calcium fluoride), etc., are enumerated.

When such a material which constitutes the hydrogen absorbing layer and hydrogen or hydrogen ion are bonded mutually, the hydride which has a value of heat of formation (standard enthalpy of formation), ΔH, being not more than −90 kJ/mol, such as LiH (lithium hydride), BaH₂ (barium hydride), CaH₂ (calcium hydride), etc., is formed.

Next, the materials (2) which have a high absorbing capability against hydrogen and hydrogen ion, and, even when which may release the once absorbed hydrogen or hydrogen ion, which are able to re-absorb them immediately after releasing, will be described as follows.

As the material of the hydrogen absorbing layer 14 which can contribute such a function, metals or metal compounds are desirable. Further, metals or metal compounds which has a high affinity for hydrogen are more desirable. As such a metal having a high affinity for hydrogen, for instance, Pd (palladium), Fe (iron), Mn (manganese), La (lanthanum), Zr (zirconium), Sc (scandium), Y (yttrium), etc., are enumerated, and as the metal compound which includes one of such metals, for instance, MnO₂ (manganese dioxide), Fe₂O₃ (iron oxide), La₂O₃ (lanthanum oxide), etc., are enumerated. Since such metals and metal compound has a high affinity for hydrogen or hydrogen ion, they absorb hydrogen or hydrogen ion with ease, and produce metal hydrides by forming bond(s) between the metal and such absorbed hydrogen or hydrogen ion. Therefore, when adapting a metal or metal compound which has a high affinity for hydrogen or hydrogen ion as the material of the hydrogen absorbing layer 14, it becomes possible to retain the hydrogen or hydrogen ion within the hydrogen absorbing layer, even when which may release the once absorbed hydrogen or hydrogen ion, which are able to re-absorb them immediately after releasing.

In either case of using the above mentioned material (1) or material (2), there is no particular limitation for the shape or configuration of the hydrogen absorbing layer 14, and the hydrogen absorbing layer 14 may be provided at any position as far as the hydrogen or hydrogen ion can be absorbed efficiently at the position.

Herein, in the organic functional device 100, when it has a layered structure wherein, for example, the first electrode 11, the organic functional component 12, and the second electrode are stacked in this order as shown in FIG. 1, the hydrogen or hydrogen ion often invades into the device from the surface side (i. e., the surface of the second electrode) or the flank sides of the device. Particularly, when any defect such as pinhole exists on the second electrode 13, it is considered that the hydrogen or hydrogen ion invades from such a pinhole. Therefore, when providing the hydrogen absorbing layer 14, it is preferable that the hydrogen absorbing layer is formed so as to block such a pinhole on the second electrode, and further so as to cover the flank sides of the layered structure.

When the hydrogen absorbing layer is provided not only to cover the surface of the second electrode 13 but also to have an area larger than the second electrode 13, i.e., to cover also the flank sides of the layered structure, it becomes possible to repress efficiently the influence of hydrogen or hydrogen ion which is generated when plasma etching or the like is employed in the manufacturing process of the organic semiconductor device and which goes around the flank sides of the layered structure.

In addition, the hydrogen absorbing layer 14 made of the above mentioned material can also be allowed to function as a mask on the plasma etching treatment. It is because the hydrogen absorbing layer 14 made of a metal or metal compound as described above has a predominant resistance to the plasma as compared to the other thin layers (e.g., organic functional component 12) in the organic semiconductor device 100. When the hydrogen absorbing layer 14 is intended to function also as the mask on the case of performing the plasma etching, the hydrogen absorbing layer 14 should be formed on and at a part other than the part to be removed by the plasma etching treatment (i.e., the part to be remained after the plasma etching).

The thickness of the hydrogen absorbing layer 14 may be set appropriately within a range that does not disturb the function of being able to absorb the hydrogen or hydrogen ion and not to release the absorbed hydrogen or hydrogen ion, regardless whether the adopted is the material (1) or (2).

Meanwhile, when the hydrogen absorbing layer 14 is also intended to function as the mask for the plasma etching treatment, the hydrogen absorbing layer should be designed so as to have a thickness which can not be consumed down to a dysfunctional thickness as the mask until the plasma etching is completed, and the thickness remained after the etching is laid within a range that does not disturb the function of being able to absorb the hydrogen or hydrogen ion and not to release the absorbed hydrogen or hydrogen ion.

In either case of using the above mentioned material (1) or material (2), there is no particular limitation for the method of forming the hydrogen absorbing layer, and any one of known procedures for preparing such a layer can be utilized. Concretely, for instance, the plasma etching method, the sputtering method, the vacuum deposition method and so on can be exemplified.

### (Protective Layer)

As shown in FIG. 1, although the protective layer 15 in the organic semiconductor device 100 according to the present invention is not essential, it may be formed on or above the organic semiconductor device as mentioned above so as to protect the individual layers which constitute the organic semiconductor device from the environmental disturbance.

As material of the protective layer 15, there is no particular limitation, and it can be selected arbitrarily from various materials as far as it can function as mentioned above. Concretely, for instance, various insulation films can be mentioned. More concretely, SiN (silicon nitride) film, SiON (silicon oxynitride), glass, SiO₂ (silicon oxide), and so on, are enumerated.

With respect to the shape or configuration of the protective layer 15 in the organic semiconductor device according to the present invention, there is also no particular limitation, and the protective layer 15 may be formed so as to cover the whole of the organic semiconductor device 100, as shown in FIG. 1. Alternatively, the protective layer 15 may be formed so as to cover a part of the organic semiconductor device 100. In addition, the protective layer 15 may be formed so as to be apart from and surrounding the layers constituting the organic semiconductor device, i.e., so as to take the so-called “sealing can type” configuration.

With respect to the thickness of the protective layer 15, there is no particular limitation for the present invention, and thus it can be set arbitrarily as far as it can function as mentioned above. For instance, a thickness of 100 nm-10 μm is usually adopted for the protective layer 15.

As a typical method for forming such a protective layer 15, the plasma CVD method can be mentioned. The plasma CVD method has been generally used for the preparation of protective film for various electrical devices. In order to prevent the hydrogen invasion into the device, wherein the hydrogen will be generated during the plasma film formation, a process capable of decreasing the hydrogen quantity in the film to be formed, particularly, under a low temperature (not more than 200° C.) condition, has been sought for. However, in the plasma CVD process using monosilane and ammonium, and, in the plasma CVD process using monosilane and nitrogen, hydrogen is compelled to generate because of the ion elimination under thermal or plasma film forming condition, as shown in the following expressions (3) and (4), respectively. The generated hydrogen tends to invade easily into the interior of the device.

3SiH₄+4NH₃→Si₃N₄+12H₂ (3)

3SiH₄+2N₂→Si₃N₄+6H₂ (4)

Even when such hydrogen generates during the protective film forming process by the plasma CVD method, the hydrogen absorbing layer 14 according to the present invention can play a role of absorbing the hydrogen thus generated and not releasing once trapped hydrogen, and therefore, the hydrogen thus generated does not invade into the interior of the device. Furthermore, the hydrogen absorbing layer 14 also plays a role of a buffer layer (stress relaxation layer) on the formation of above mentioned protective layer 15.

Although the plasma CVD method has been mentioned as a typical method for forming the protective layer in the above description, the method for forming the protective layer is not limited to this method. Other CVD methods such as thermal CVD, Cat-CVD (Catalytic CVD), LPCVD (Low Pressure CVD), photo CVD, APCVD (Atmospheric Pressure CVD), laser CVD, RTPCVD (Rapid Thermal Pressure CVD) may be adaptable. Further, the protective layer of the sealing can type may be prepared. When the sealing can type protective layer is formed, the protective layer can play a role of absorbing hydrogen or hydrogen ion existing in the interior of the sealing can after the formation of the protective layer.

### (2) Another Embodiment of the Organic Semiconductor Device According to the Present Invention

FIG. 2 illustrates an embodiment of the organic semiconductor device 200 of the present invention which is applied to a panel with division wall.

Since the respective layers which constitute the organic semiconductor device 200 in this embodiment shown in FIG. 2 correspond to the individually correlative layers which constitute the above mentioned semiconductor device shown in FIG. 1, detailed descriptions for these layers are omitted in order to avoid redundancy.

As shown in FIG. 2, the hydrogen absorbing layer 14 can provide in the panel with the division wall 16 of the organic semiconductor device 200. Even in this case, the hydrogen absorbing layer 14 can possess the function of absorbing hydrogen or hydrogen atom and not releasing the absorbed absorbing hydrogen or hydrogen atom. In addition, the hydrogen absorbing layer can play a role of eliminating the damage due to the plasma and a role of preventing the outgassing.

The organic semiconductor device according to the present invention can be also used for various usages in addition to such a panel with division wall 16. Concretely, for instance, organic EL, organic EL display, organic solar cell, organic transistor, semiconductor laser, etc., are enumerated.

When the organic semiconductor device according to the present invention is constructed as a top emission type (i.e., the configuration of taking light out in an upward direction) organic EL, it is preferable that the visible light transmittance through the hydrogen absorbing layer is high. Concretely, the visible light transmittance of the hydrogen absorbing layer is preferably to be not less than 80%.

Next, the method for manufacturing the organic semiconductor device according to the present invention will be explained specifically with reference to the drawings.

### (3) Method for Manufacturing the Organic Semiconductor Device According to the Present Invention

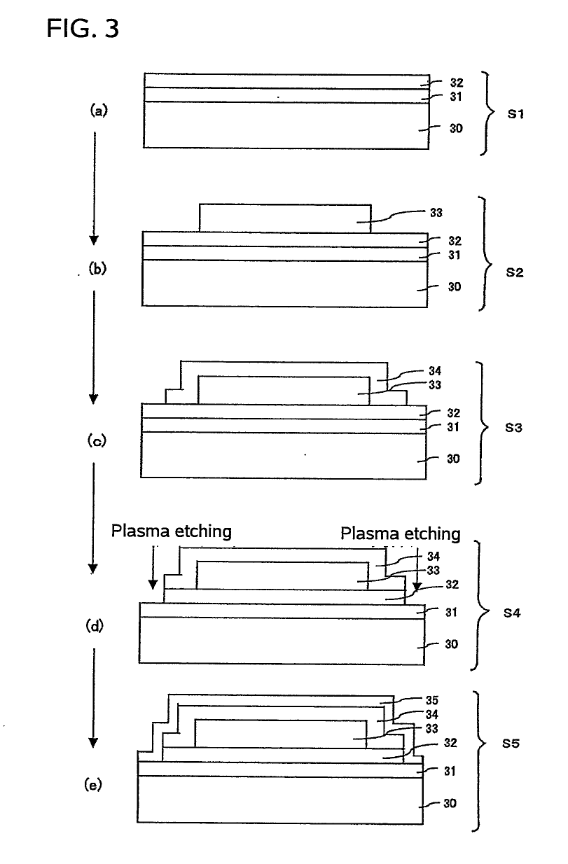

FIG. 3 is a process drawing which illustrates an embodiment of the manufacturing method of the organic semiconductor device according to the present invention.

As illustrated in FIG. 3, the method for manufacturing the organic semiconductor device equipped with the hydrogen absorbing layer according to the present invention comprises a first step S1 at which an organic functional component 32 is formed over a substrate 30 via a first electrode 31; a second step S2 at which a second electrode 33 having a prescribed pattern is formed on the organic functional component 32; a third step S3 at which a hydrogen absorbing layer 34 is formed on and at a part which corresponds to the intended part of organic functional component 32 which should be remained after etching; and a fourth step S4 at which the organic functional component 32 located at a part on which the hydrogen absorbing layer 34 has not been formed at the third step is etched out by etching over the hydrogen absorbing layer 34 after the third step.

Now, the respective steps will be described in detail.

Herein, because the respective layers which constitute the organic semiconductor device in the respective steps are the same as mentioned above, the explanations thereof are omitted.

### <First Step>

As shown in FIG. 3(a), this step is the step S1 at which the first electrode 31 is formed on the substrate 30 and then the organic functional component 32 is further formed on the first electrode 31 so as to layer the organic functional component 32 over a substrate 30 via a first electrode 31.

### <Second Step>

As shown in FIG. 3(b), this step is the step S2 at which the second electrode 33 having a prescribed pattern is formed on the organic functional component 32.

### <Third Step>

As shown in FIG. 3(c), this step is the step S3 at which the hydrogen absorbing layer 34 is formed on and at a part which corresponds to the intended part of the organic functional component 32 which should be remained after etching. Providing that the hydrogen absorbing layer 34 is formed, it becomes possible to absorb the hydrogen or hydrogen ion with the hydrogen absorbing layer 34, and not to release the absorbed hydrogen or hydrogen ion, and therefore, it becomes possible to prevent the invasion of hydrogen or hydrogen ion into the respective layers which constitute the organic semiconductor device.

### <Fourth Step>

As shown in FIG. 3(d), this step is the step S4 at which the organic functional component 32 located at a part on which the hydrogen absorbing layer 34 has not been formed at the third step is etched out by etching over the hydrogen absorbing layer 34 after the third step.

Concretely, this step S4 is the etching step where the unnecessary part of the organic functional component 32 in the organic semiconductor device is etched out. More specifically, for instance, at the part corresponding to the lead-out part for the electrode, or the like, the organic functional component 32, and optionally, other layers is etched out.

As described above, the hydrogen absorbing layer 34 plays a role of absorbing hydrogen or hydrogen ion and not releasing the absorbed hydrogen or hydrogen ion. Further, the hydrogen absorbing layer 34 made of a metal or metal compound also plays a role of a protective mask which is used when the organic functional component 32 is processed to a prescribed shape, in addition to the former role. It is because the hydrogen absorbing layer 34 made of the metal or metal compound has a predominant resistance to the plasma as compared to the organic functional component 32.

During this step, the organic functional component 32 located at a part on which the hydrogen absorbing layer 34 has not been formed is selectively and gradually etched and removed out. Finally, the organic functional component 32 can be patterned into the prescribed shape.

As the etching method utilized in this method according to the present invention, there is no particular limitation as far as it can etch predominantly the organic functional component over the hydrogen absorbing layer. Thus, various procedures known in the art may be adaptable. A concrete example of such an etching method, for instance, a method, wherein a mixture gas in which a rare gas (e.g., Ar or Kr) is added to oxygen is used, oxygen plasma is created by RF discharge, and thus formed plasma is used for etching, can be exemplified. Although a mixture gas of oxygen and a rare gas (e.g., Ar or Kr) is used in the above example, a sole oxygen gas is also usable, and a sole rare gas is usable, too. The plasma discharge may be formed by using a capacitive coupling type, anode coupling or cathode coupling. In such cases, there is no particular limitation with respect to the gas species and the plasma discharge mode, and any one of various methods known in the art may be adaptable.

Herein, the hydrogen absorbing layer 34 must retain the functions of absorbing hydrogen or hydrogen ion, of not releasing the absorbed hydrogen or hydrogen ion, even after the etching. Therefore, it is necessary that the hydrogen absorbing layer 34 remains as the mask until the etching of the organic functional component 32 is completed, and leaves a thickness within a range that does not disturb the function of being able to absorb the hydrogen or hydrogen ion and not to release the absorbed hydrogen or hydrogen even after the etching process. Therefore, the thickness of the hydrogen absorbing layer 34 can be varied arbitrarily depending on the kind and thickness of the organic functional component 32 as the target of etching, or other factors.

### <Fifth Step>

This step is the step S5 at which the protective layer 35 is provided so as to cover the organic semiconductor device after the above mentioned fourth step S4. In the case of providing the protective layer 35, the hydrogen absorbing layer used in the fourth step can play a role of absorbing hydrogen or hydrogen ion and not releasing the absorbed hydrogen or hydrogen ion, as well as a role of a buffer layer (stress relaxation layer, plasma damage protecting layer) on the formation of the protective layer.

1-15. (canceled)

16. An organic semiconductor device comprises at least a substrate, a first electrode, an organic functional component, and a second layer, which are layered in this order, and which further comprises a hydrogen absorbing layer which is provided onto or above the second layer, wherein the hydrogen absorbing layer comprises one member selected from the group consisting of alkaline metals, alkaline earth metals, metals having affinity for hydrogen, and metal compounds including any one of these metals as metal component thereof.

17. The organic semiconductor device according to claim 16, wherein the hydrogen absorbing layer is able to absorb hydrogen and hydrogen ion, and which does not release the absorbed hydrogen or hydrogen ion.

18. The organic semiconductor device according to claim 16, wherein said alkaline metal is one member selected from the group consisting of Li (lithium), Na (Sodium), K (potassium), Rb (rubidium) and Cs (cesium).

19. The organic semiconductor device according to claim 16, wherein said metal compound is one member selected from the group consisting of lithium fluoride, lithium oxide, and potassium oxide.

20. The organic semiconductor device according to claim 16, wherein at least a part of the organic hydrogen absorbing layer is covered with a protective layer, and the covered part of the hydrogen absorbing layer is contact with the protective layer.

21. The organic semiconductor device according to claim 20, wherein said protective layer comprises one member selected from the group consisting of SiN (silicon nitride) film, SiON ((silicon oxynitride) film, and SiO₂ (silicon oxide) film.

22. The organic semiconductor device according to claim 20, wherein said protective layer is formed by plasma CVD method.

23. The organic semiconductor device according to claim 16, wherein said organic semiconductor device is one of organic EL device, organic solar cell, organic transistor, and semiconductor laser device.

24. The organic semiconductor device according to claim 20, wherein said organic semiconductor device is one of organic EL device, organic solar cell, organic transistor, and semiconductor laser device.

25. The organic semiconductor device according to claim 16, wherein said hydrogen absorbing layer is the layer in which the value of heat of formation (standard enthalpy of formation), ΔH, of hydride, which is formed by the hydrogen absorbing layer and hydrogen or hydrogen ion when hydrogen or hydrogen ion is absorbed into the hydrogen absorbing layer, is not more than −90 kJ/mol.

26. The organic semiconductor device according to claim 20, wherein said hydrogen absorbing layer is the layer in which the value of heat of formation (standard enthalpy of formation), ΔH, of hydride, which is formed by the hydrogen absorbing layer and hydrogen or hydrogen ion when hydrogen or hydrogen ion is absorbed into the hydrogen absorbing layer, is not more than −90 kJ/mol.

27. The organic semiconductor device according to claim 16, wherein said hydrogen absorbing layer has a mean light transmittance through the hydrogen absorbing layer in visible light range of not less than 80%.

28. The organic semiconductor device according to claim 20, wherein said hydrogen absorbing layer has a mean light transmittance through the hydrogen absorbing layer in visible light range of not less than 80%.
